(19) United States
(12) Patent Application Publication
(10) Pub. No.: US 2011/0084325 A1
(43) Pub. Date: Apr. 14, 2011

(54) DRAM STRUCTURE WITH A LOW PARASITIC CAPACITANCE AND METHOD OF MAKING THE SAME

(76) Inventors: Hsiao-Lei Wang, Tainan City (TW); Chung-Lin Huang, Taoyuan County (TW); Hung-Chang Liao, Taipei City (TW); Shih-Lung Chen, Taipei City (TW)

(21) Appl. No.: 12/649,361

(22) Filed: Dec. 30, 2009

(30) Foreign Application Priority Data
Oct. 14, 2009 (TW) 098134749

(51) Int. Cl. H01L 27/108; H01L 21/762

(52) U.S. Cl. 257/296; 438/296; 257/382; 257/386; 257/E21.546; 257/E27.084

(57) ABSTRACT

An oxide spacer for stack DRAM gate stack is described, including: a semiconductor substrate with a memory array region and a periphery region, a plurality of gates disposed within the memory array region and the periphery region respectively, a silicon oxide spacer disposed on the gates, where the polysilicon contact plugs are formed by polysilicon deposition and chemical mechanical polish. After polysilicon contact plugs are formed, a silicon oxide layer is deposited to isolate the contacts and gate. The silicon oxide layer on top of contact plug is removed by chemical mechanical polish achieve planarization.

### BACKGROUND OF THE INVENTION

1. Field of the Invention

The present invention relates to a DRAM structure and method of making the same, more particularly to a DRAM structure with a silicon oxide spacer.

2. Description of the Prior Art

DRAM, which is one of the most popular volatile memories utilized today, is composed of many memory cells. Each memory cell includes a MOS transistor and at least one capacitor connected in series. By electrically connecting to word lines and bit lines, the DRAM can be read and programmed. Generally, the bit lines are formed by forming via holes in the dielectric layer and filling up the via holes with a conductive material.

In a conventional fabricating method of DRAM, a silicon oxide dielectric layer is formed to cover the MOS transistor. Then, a plurality of via holes are formed in the silicon oxide dielectric layer. The via hole is formed by an etching process based on the different etching ratio of the silicon nitride spacer on the MOS transistor and the silicon oxide dielectric layer. The silicon oxide dielectric layer has a high etching rate to the etchant, and the silicon nitride spacer has a low etching rate to the etchant. Therefore, the silicon nitride spacer will still remain on the gate of the MOS transistor even after the etching process and the gate is protected by the silicon nitride spacer during the etching process. After that, a contact plug can be formed in each via hole and then other interlayer dielectric layers will be formed on the silicon oxide dielectric layer. Finally, a capacitor can be formed on interlayer dielectric layer and connects to the MOS transistor electrically.

However, the silicon nitride spacer leads to higher parasitic capacitance, which adversely affects the performance of the memory device.

### SUMMARY OF THE INVENTION

Accordingly, it is the primary object of the present invention to provide a method for fabricating a contact plug without utilizing silicon nitride spacer.

According to the claimed in invention, a method of forming a DRAM structure with a low parasitic capacitance includes: a substrate having a memory array region and a periphery region is provided. Next, a plurality of gates disposed within the memory array region and the periphery region respectively are formed. Then, a silicon oxide spacer is formed on each of the gates. After that, a source/drain doped region is formed in the substrate adjacent to each of the gates. Finally, a polysilicon layer is formed on the source/drain doping region, and the polysilicon layer is aligned with a top surface of each of the gates.

According to the claimed in invention, a DRAM structure with a low parasitic capacitance comprises, a substrate comprising a memory array region and a periphery region, a plurality of gates positioned in the memory array region and the periphery region, a source/drain doped region disposed in the substrate next to each of the gates, a silicon oxide spacer positioned on each of the gates and a polysilicon contact plug positioned on the source/drain doped region and contacting the silicon oxide spacer.

According to the claimed in invention, another structure of a DRAM structure with a low parasitic capacitance includes: a substrate comprising a memory array region and a periphery region, a plurality of gates positioned in the memory array region and the periphery region, a source/drain doped region disposed in the substrate next to each of the gates, a silicon oxide spacer positioned on each of the gates, a barrier positioned on the silicon oxide spacer, a polysilicon contact plug positioned on the source/drain doped region in the memory array region and contacting the silicon oxide spacer and a metal contact plug positioned on the source/drain doped region in the periphery region.

The feature of the present invention is that the silicon nitride spacer is replaced by the silicon oxide spacer, because the dielectric constant of the silicon oxide is smaller than that of the silicon nitride. The DRAM with silicon oxide spacer may have lower parasitic capacitance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 10 are schematic cross-sectional diagrams showing a method for fabricating a low parasitic capacitance contact plug of DRAM.

### DETAILED DESCRIPTION

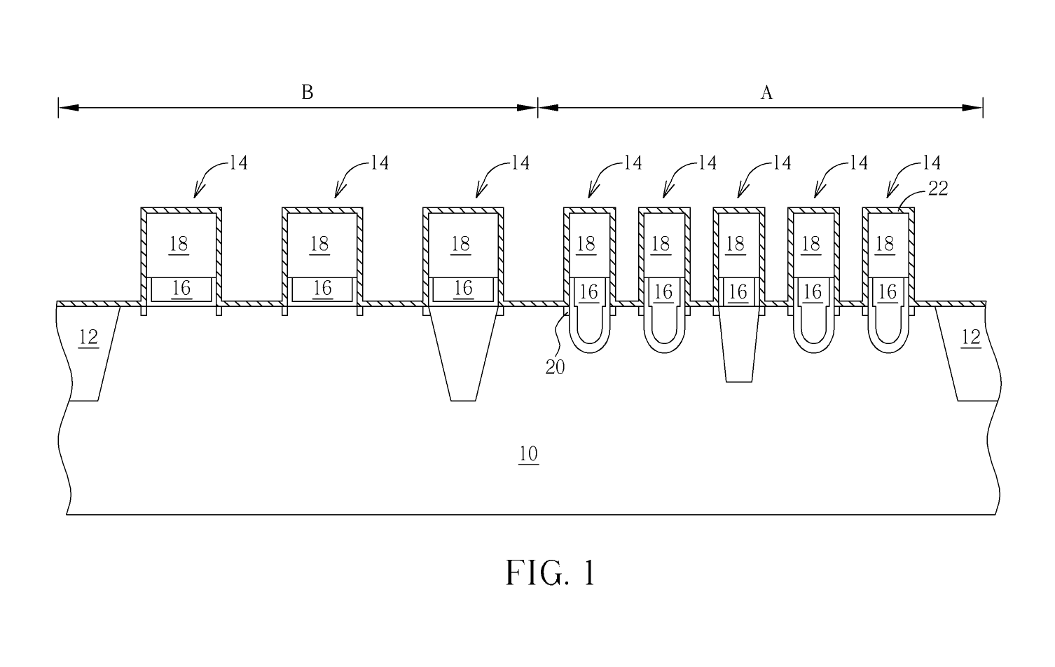

FIG. 1 to FIG. 10 are schematic cross-sectional diagrams showing a method of forming a DRAM structure with a low parasitic capacitance. As shown in FIG. 1, a substrate 10 including a memory array region A and a periphery region B is provided. Furthermore, a STI structure 12 is disposed in the memory array region A and the periphery region B. Then, a plurality of gates 14 are formed on the memory array region A and the periphery region B. Each of the gates 14 includes a gate conductor 16 and a cap layer 18. Furthermore, the gates 14 can be recessed gates.

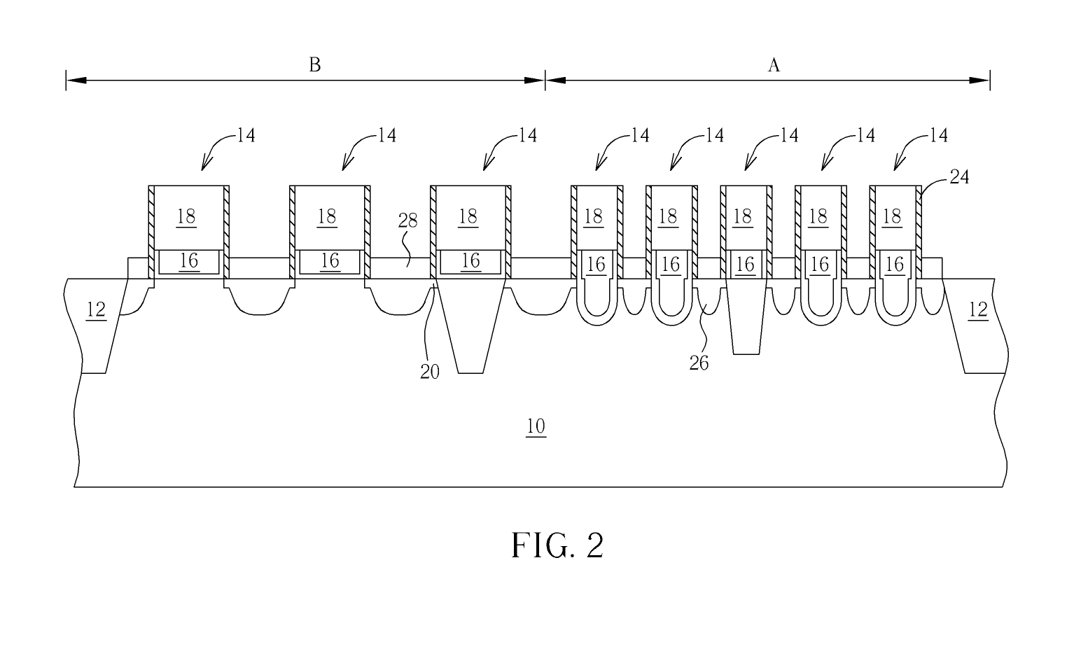

After that, an ion implantation process is performed to form a lightly doped region 20 in the substrate 10 next to each of the gates 14. Then, a silicon oxide layer 22 is formed conformally on the gates 14, the substrate 10 and the STI structure 12. Later, as shown in FIG. 2, an anisotropic etching process is performed to remove part of the silicon oxide layer 22 to form a silicon oxide spacer 24 on each of the gates 14. Then, the gates 14 and the silicon oxide spacer 24 are taken as a hard mask to form a source/drain doping region 26 in the substrate 10 next to the lightly doped region 20.

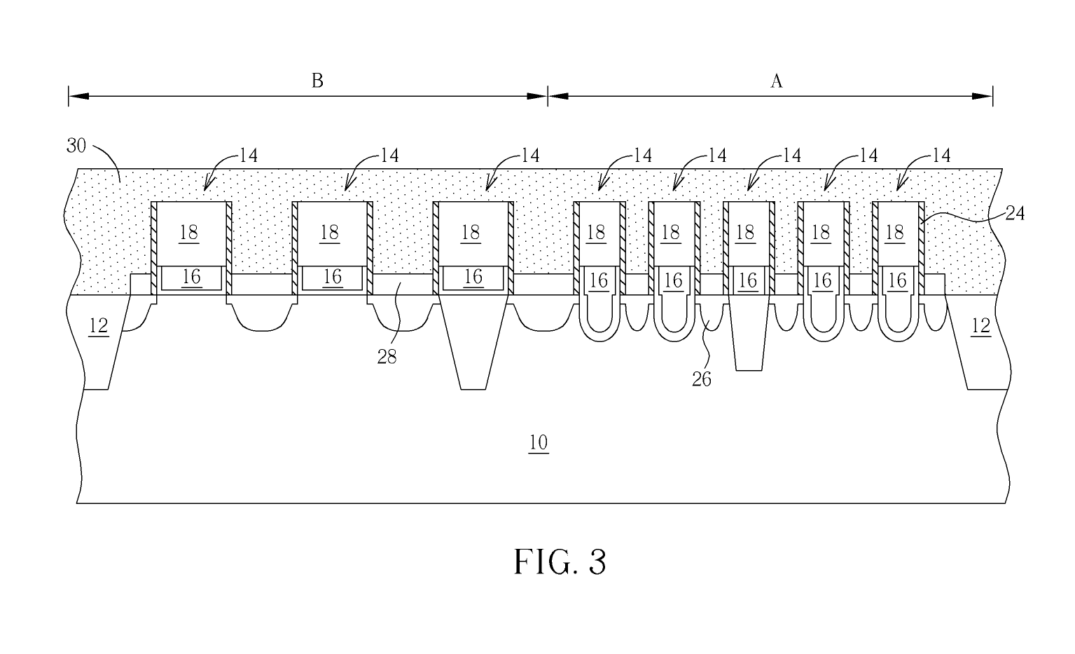

Next, a silicon epitaxial layer 28 is formed optionally on source/drain doped region 26 by an epitaxial growth process. As shown in FIG. 3, a polysilicon layer 30 is blankly formed to cover the gates 14, and the STI structure 12, and the space between each of the gates 14. It is noteworthy that there is not any silicon nitride spacer that is formed after the silicon oxide spacer 24 and the polysilicon layer 30 is formed.

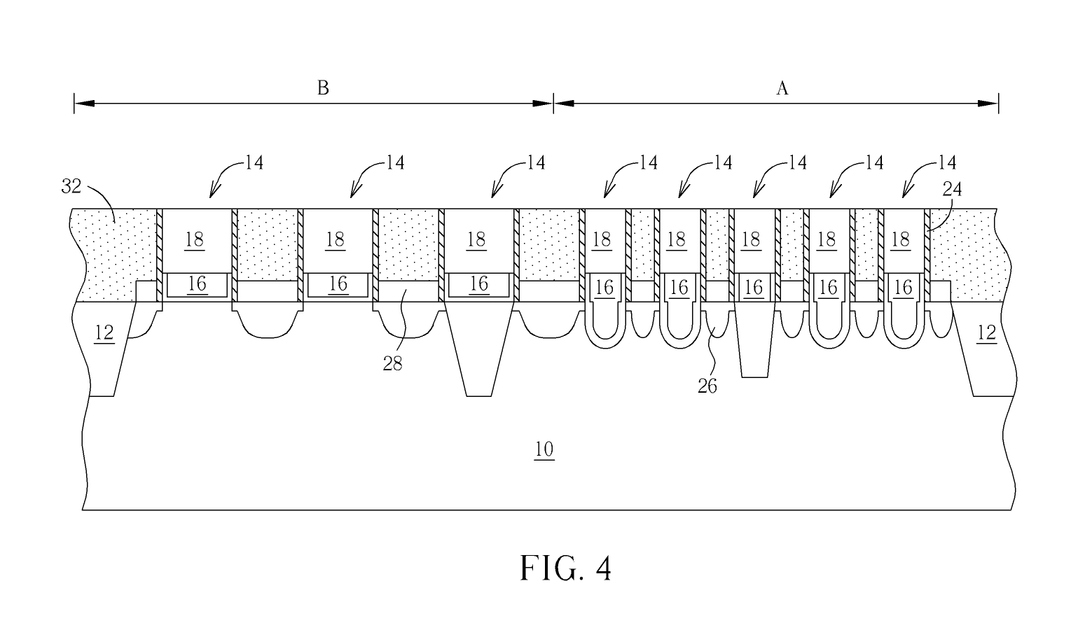

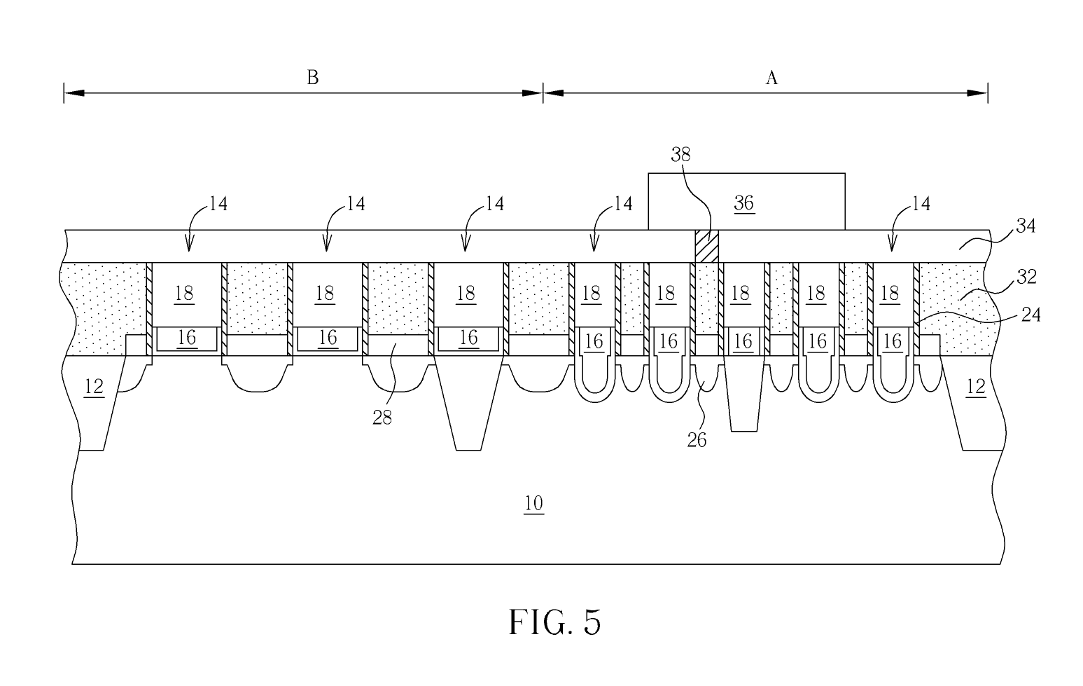

As shown in FIG. 4, a chemical mechanical polishing process (CMP) is performed to align the top surface of the polysilicon layer 30 with the top surface of the gates 14, and a plurality of polysilicon contact plugs 32 is formed on the silicon epitaxial layer 28. After that, a patterned mask (not shown) is formed to cover the gates 14 in memory array region A and the periphery region B, and part of the polysilicon layer 30. The polysilicon layer 30 on the STI structure 12 and the polysilicon layer 30 not belonging to the polysilicon contact plug 32 are exposed. Then, the exposed polysilicon layer 30 is removed and the patterned mask is removed afterwards. Then, a silicon oxide layer (not shown) fills up the region between the gates 14 and the polysilicon contact plug 32. In other words, the silicon oxide fills up the region originally occupied by the polysilicon layer 30 not belonging to the polysilicon contact plug 32. Next, the aforesaid silicon oxide layer is planarized by a CMP process. At this point, the polysilicon contact plug 32 contacting the source/drain doping region 26 in the memory array region A and the periphery region B is finished. Later, as shown in FIG. 5, an interlayer dielectric layer 34 can be formed on the gates 14 and the polysilicon contact plug 32, and a stack capacitor 36 can be formed on the interlayer dielectric layer 34. A contact plug 38 is formed to electrically contact the stack capacitor 36 and the polysilicon contact plug 32. Now, the DRAM cell is completed.

According to another preferred embodiment of the present invention, the polysilicon plug in the periphery region B can be replaced by a metal contact plug, the fabricating method is described as follows.

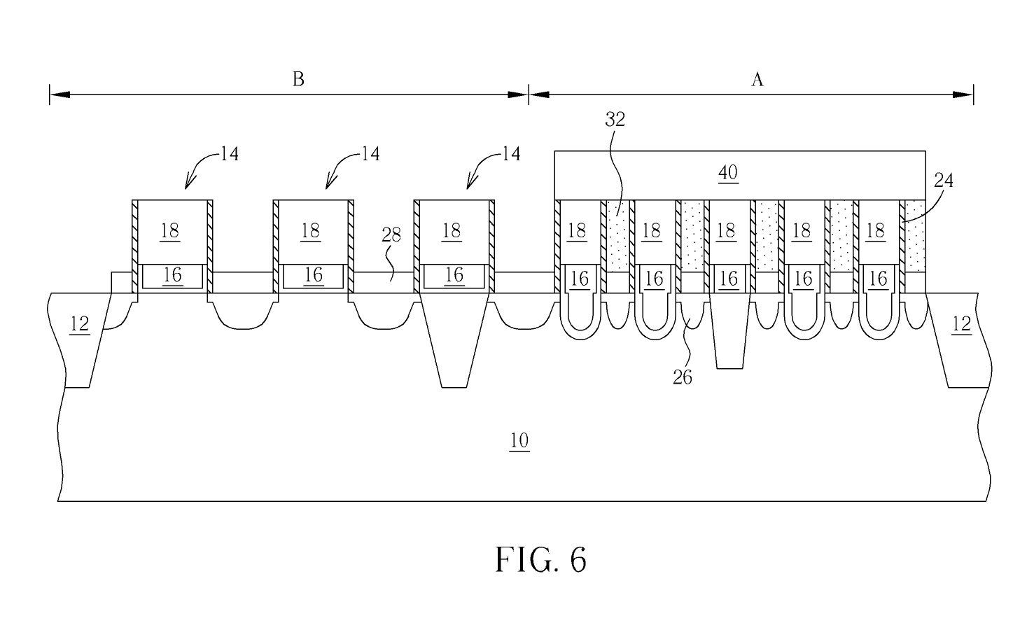

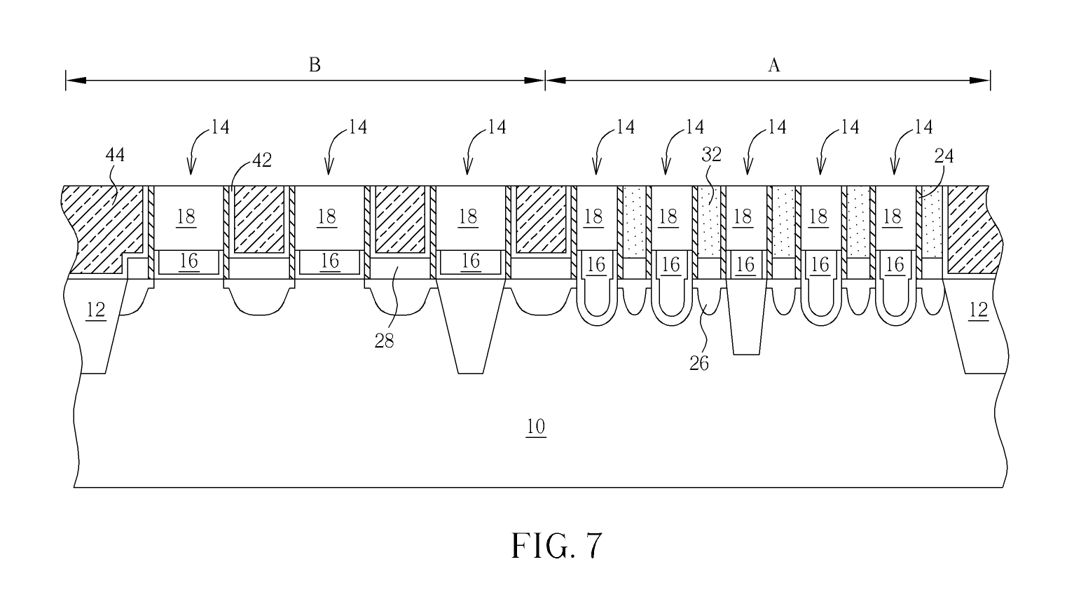

After the step of chemical polishing the polysilicon layer 30 shown in FIG. 4 is finished, as shown in FIG. 6, a patterned mask layer 40 is formed to cover the gates 14 and the polysilicon contact plug 32 in the memory array region A and exposes the polysilicon layer 30 in the periphery region B, the polysilicon layer 30 on the STI structure 12 in the memory array region A and the periphery region B, and the polysilicon layer 30 not belonging to the polysilicon contact plug 32 in the memory array region A. Then, the exposed polysilicon layer 30 is removed. In other words, all of the polysilicon layer 30 in the memory array region A and the periphery region B are removed except the polysilicon layer 30 serving as the polysilicon contact plug 32 in the memory array region A. As shown in FIG. 7, the patterned mask layer 40 is removed. Next, a barrier 42 such as a silicon nitride is formed conformally on each of the gates in the periphery region B and the surface of the substrate 10. Later, a first dielectric layer 44 such as borophosphosilicate glass (BPSG) is formed to cover the barrier 42 and fill up the space between each of the gate 14 in the periphery region B and the space between each of the gates 14 and the polysilicon contact plug 32 in the memory array region A. After that, the first dielectric layer 44 is planarized to be aligned with the top surface of the gates 14 in the periphery region B.

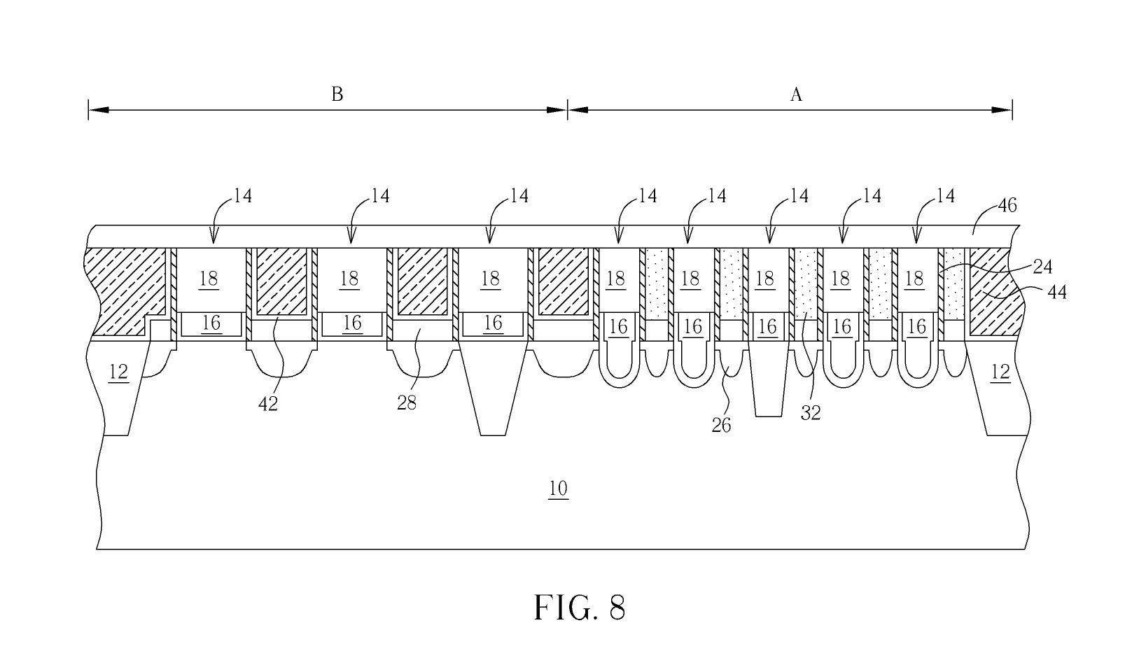

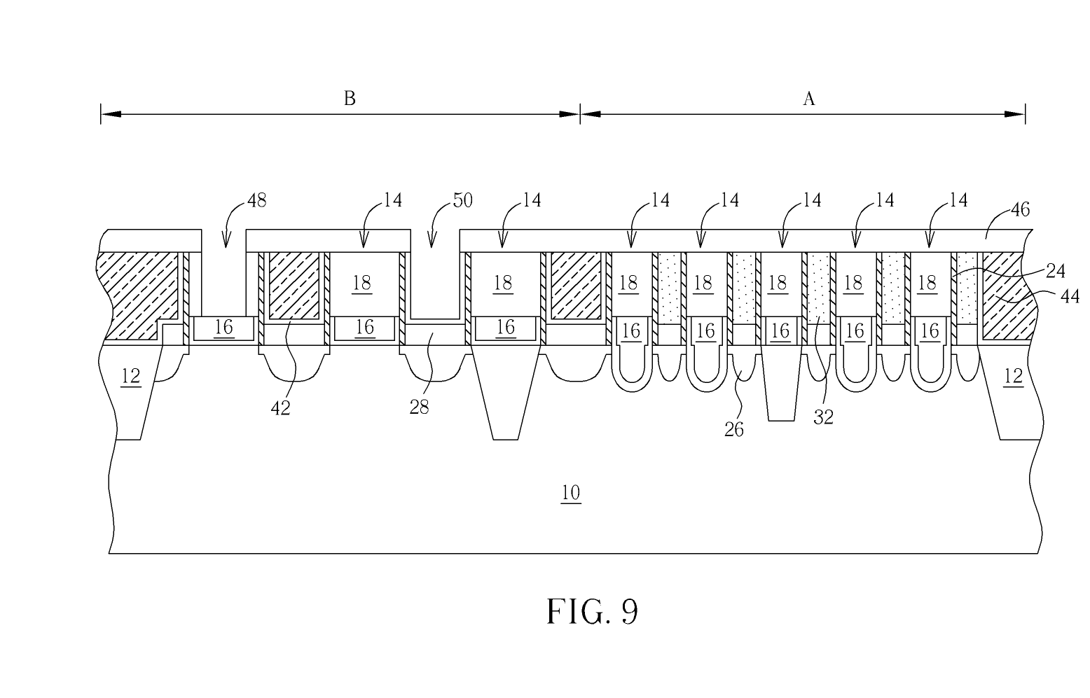

As shown in FIG. 8, a second dielectric layer 46 such as silicon oxide is formed on the first dielectric layer 44, the polysilicon contact plug 32 in the memory array region A and the gates 14. As shown in FIG. 9, another patterned mask (not shown) is formed to cover part of the second dielectric layer 46. Then, part of the second dielectric layer 46 is removed. Meanwhile, the cap layer 18 of one of the gates 14 in the periphery region B and the first dielectric layer 44 on the source/drain doping region 26 belong to one of the gates are also removed to formed a first opening 48 and a second opening 50, respectively.

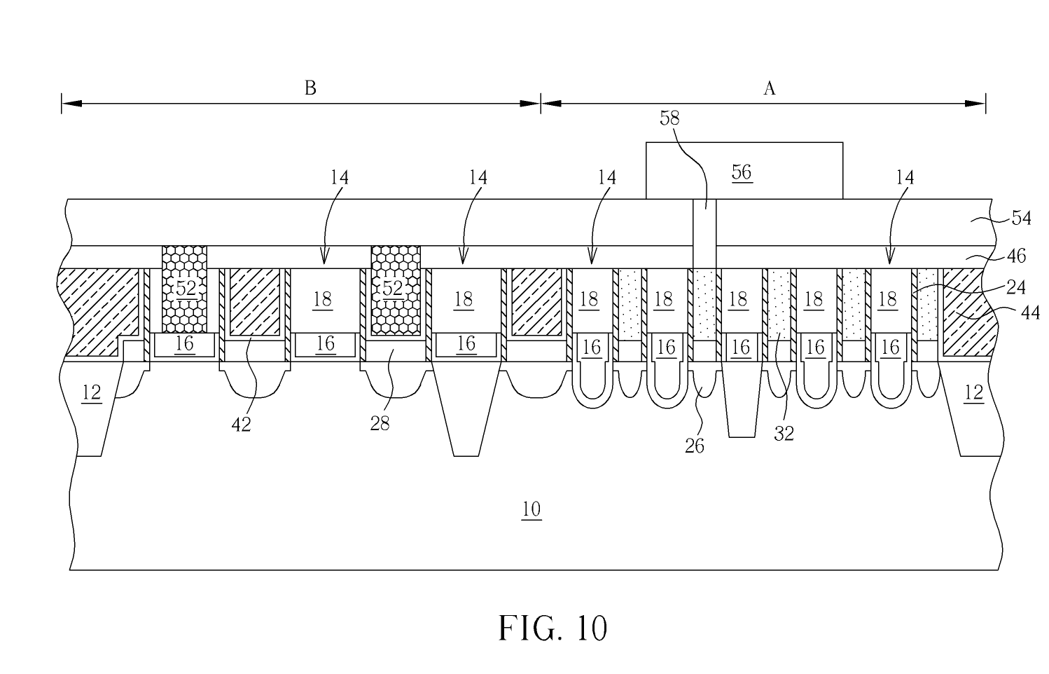

As shown in FIG. 10, a conductive layer such as tungsten, titanium, or aluminum fills up the first opening 48 and the second opening 50 respectively to serve as a metal plug 52. Later, an interlayer dielectric layer 54 can be formed on the second dielectric layer 46 and a contact plug 58 coupling to the source/drain region 26 is formed in the interlayer dielectric layer 54 and the second dielectric layer 46. Then, a stack capacitor 56 can be formed on the interlayer dielectric layer 54, and the stack capacitor 56 couples to the contact plug 58. At this point, the DRAM cell is completed.

The present invention also provides a DRAM structure with a low parasitic capacitance. As shown in FIG. 5, a DRAM structure with a low parasitic capacitance includes a substrate 10 having a memory array region A and a periphery region B, a plurality of gates 14 disposed in the memory array region A and the periphery region B, a source/drain doped region 26 disposed in the substrate 10 next to each of the gates 14, a silicon epitaxial layer 28 disposed optionally on the source/drain doped region 26, a silicon oxide spacer 24 disposed on each of the gates 14, and a polysilicon contact plug 32 disposed on the source/drain doped region 26 next to each of the gates 14 in the memory array region A and the periphery region B. It is noteworthy that there is not any silicon nitride spacer disposed between the polysilicon contact plug 32 and the silicon oxide spacer 24.

The present invention provides another DRAM structure with a low parasitic capacitance. As shown in FIG. 10, a DRAM structure with a low parasitic capacitance includes a substrate 10 having a memory array region A and a periphery region B, a plurality of gates 14 disposed in the memory array region A and the periphery region B, each of the gates including a gate conductor 16, a source/drain doped region 26 disposed in the substrate 10 next to each of the gates 14, a silicon epitaxial layer 28 disposed optionally on the source/drain doped region 26, a silicon oxide spacer 24 disposed on each of the gates 14, a barrier 42 disposed on the silicon oxide spacer 24 on the gates in the periphery region B, a polysilicon contact plug 32 disposed on the source/drain doped region 26 next to each of the gates 14 in the memory array region A, and a metal contact plug 52 disposed on the source/drain doped region 26 next to one of the gates 14 in the periphery region B, and disposed on the gate conductor 16 of one of the gates 14 in the periphery region B. It is noteworthy that there is not any silicon nitride spacer disposed between the polysilicon contact plug 32 and the silicon oxide spacer 24, and between the metal contact plug 52 and the silicon oxide spacer 24. The polysilicon contact plug 32 contacts the silicon oxide spacer 24 directly.

The feature of the present invention is that the gate of the DRAM cell uses silicon oxide as spacer. Comparing to the conventional DRAM structure which uses the silicon nitride used in as a spacer, the silicon oxide spacer of the present invention may lower the parasitic capacitance.

Those skilled in the art will readily observe that numerous modifications and alterations of the device and method may be made while retaining the teachings of the invention.

What is claimed is:

1. A method of forming a DRAM structure with a low parasitic capacitance, comprising:
providing a substrate having a memory array region and a periphery region;
forming a plurality of gates disposed within the memory array region and the periphery region respectively;
forming a silicon oxide spacer on each of the gates;
forming a source/drain doped region in the substrate adjacent to each of the gates; and
forming a polysilicon layer on the source/drain doping region, and the polysilicon layer being aligned with a top surface of each of the gates.

2. The method of forming a DRAM structure with a low parasitic capacitance of claim 1, wherein each of the gates comprises a gate conductor and a cap layer.

3. The method of forming a DRAM structure with a low parasitic capacitance of claim 2, further comprising:
after forming the polysilicon layer on the source/drain doped region, removing the polysilicon layer in the periphery region and exposing the source/drain doped region in the periphery region;
forming a barrier on the silicon oxide spacer on each of the gates disposed in the periphery region;
filling up the space between the gates in the periphery region by a first dielectric layer and a top surface of the first dielectric layer being aligned with the top surfaces of each of the gates in the periphery region;
removing the cap layer of at least one of the gate to form a first opening, and forming a second opening in the first dielectric layer on the source/drain doped region next to one of the gates; and
filling up the first opening and the second opening by a metal layer.

4. The method of forming a DRAM structure with a low parasitic capacitance of claim 3, further comprising:
after forming the first dielectric layer and before forming the first opening the second opening, forming a second dielectric layer to cover the gates, the first dielectric layer and the polysilicon layer.

5. The method of forming a DRAM structure with a low parasitic capacitance of claim 3, further comprising: disposing a STI structure in the memory array region and the periphery region respectively.

6. The method of forming a DRAM structure with a low parasitic capacitance of claim 5, wherein when the polysilicon layer is formed on the source/drain doped region, the polysilicon layer also covers the STI structure.

7. The method of forming a DRAM structure with a low parasitic capacitance of claim 6, wherein when the polysilicon layer in the periphery region is removed, the polysilicon layer on the STI structure is also removed.

8. The method of forming a DRAM structure with a low parasitic capacitance of claim 1, further comprising:
forming a silicon epitaxial layer on the source/drain doped region before forming the silicon oxide spacer.

9. The method of forming a DRAM structure with a low parasitic capacitance of claim 1, wherein the method of forming the silicon oxide spacer comprises:
forming a silicon oxide layer covering each of the gates and the surface of the substrate; and
performing an anisotropic etching to etch the silicon oxide layer to form the silicon oxide spacer.

10. The method of forming a DRAM structure with a low parasitic capacitance of claim 1, wherein no silicon nitride spacer is formed before the polysilicon layer is formed and after the silicon oxide spacer is formed.

11. A DRAM structure with a low parasitic capacitance, comprising a substrate comprising a memory array region and a periphery region;
a plurality of gates positioned in the memory array region and the periphery region;
a source/drain doped region disposed in the substrate next to each of the gates;
a silicon oxide spacer positioned on each of the gates; and
a polysilicon contact plug positioned on the source/drain doped region and contacting the silicon oxide spacer.

12. The DRAM structure with a low parasitic capacitance of claim 11, further comprising a silicon epitaxial layer disposed on the source/drain doped region.

13. The DRAM structure with a low parasitic capacitance of claim 11, wherein there is not any silicon nitride spacer between the silicon oxide spacer and the polysilicon contact plug.

14. A DRAM structure with a low parasitic capacitance, comprising,
a substrate comprising a memory array region and a periphery region;
a plurality of gates positioned in the memory array region and the periphery region;
a source/drain doped region disposed in the substrate next to each of the gates;
a silicon oxide spacer positioned on each of the gates;
a barrier positioned on the silicon oxide spacer;
a polysilicon contact plug positioned on the source/drain doped region in the memory array region and contacting the silicon oxide spacer; and
a metal contact plug positioned on the source/drain doped region in the periphery region.

15. The DRAM structure with a low parasitic capacitance of claim 14, wherein each of the gates further comprises a gate conductor.

16. The DRAM structure with a low parasitic capacitance of claim 15, wherein the metal contact plug is also positioned on the gate conductor of one of the gates.

17. The DRAM structure with a low parasitic capacitance of claim 14, wherein there is not any silicon nitride spacer between the silicon oxide spacer and the polysilicon contact plug.

18. The DRAM structure with a low parasitic capacitance of claim 14, wherein there is not any silicon nitride spacer between the silicon oxide spacer and the metal contact plug.
